(19) United States
(12) Patent Application Publication
(10) Pub. No.: US 2013/0234699 A1
(43) Pub. Date: Sep. 12, 2013

(54) POWER SUPPLY MONITORING SYSTEM AND METHOD THEREOF

(71) Applicant: MING YU, Shenzhen City (CN)

(72) Inventor: MING YU, Shenzhen City (CN)

(21) Appl. No.: 13/632,399

(22) Filed: Oct. 1, 2012

(30) Foreign Application Priority Data
Mar. 8, 2012 (CN) 201210059560.5

(51) Int. Cl. G01R 21/00

(52) U.S. Cl. 324/113

(57) ABSTRACT

A power supply monitoring system for monitoring power supplied to electronic components is disclosed. The power supply monitoring system includes a monitoring bus, a monitoring module, an interrupt module, and a data storage module. The monitoring bus is connected to electronic components. The monitoring module monitors variations of levels of power supplied to the electronic components via the monitoring bus. The interrupt module interrupts the monitoring module when the monitoring module monitored the variations of levels of power supplied to the electronic components. The data storage module is connected to the interrupt module. The interrupt module stores the variations of levels of power supplied to the electronic components into the data storage module when the interrupt module is interrupted.

### BACKGROUND

1. Technical Field

The present disclosure relates to a power supply monitoring system and method thereof.

2. Description of Related Art

Computers have power supply units to provide power to electronic components in the computers. The power supply unit is connected to different electronic components of the computer and provides power to the electronic components. When the computer is in operating, power provided by the power supply unit varies according to running states of the electronic components. However, the electronic components may generate wrong signals, which may cause the power supply unit to provide wrong power and cause damages to the electronic components. To debug the wrong signals from the electronic components, it may be necessary to monitor the power supplied to the electronic components.

Therefore, there is room for improvement within the art.

### BRIEF DESCRIPTION OF THE DRAWINGS

Many aspects of the embodiments can be better understood with reference to the following drawings. The components in the drawings are not necessarily drawn to scale, the emphasis instead being placed upon clearly illustrating the principles of the embodiments. Moreover, in the drawings, like reference numerals designate corresponding parts throughout the several views.

FIG. 1 is a block diagram of a power supply monitoring system according to an embodiment.

FIG. 2 is another block diagram of the power supply monitoring system of FIG. 1.

FIG. 3 is a flow chart of a power supply monitoring method according to an embodiment.

### DETAILED DESCRIPTION

The disclosure is illustrated by way of example and not by way of limitation in the figures of the accompanying drawings in which like references indicate similar elements. It should be noted that references to “an” or “one” embodiment in this disclosure are not necessarily to the same embodiment, and such references mean “at least one.”

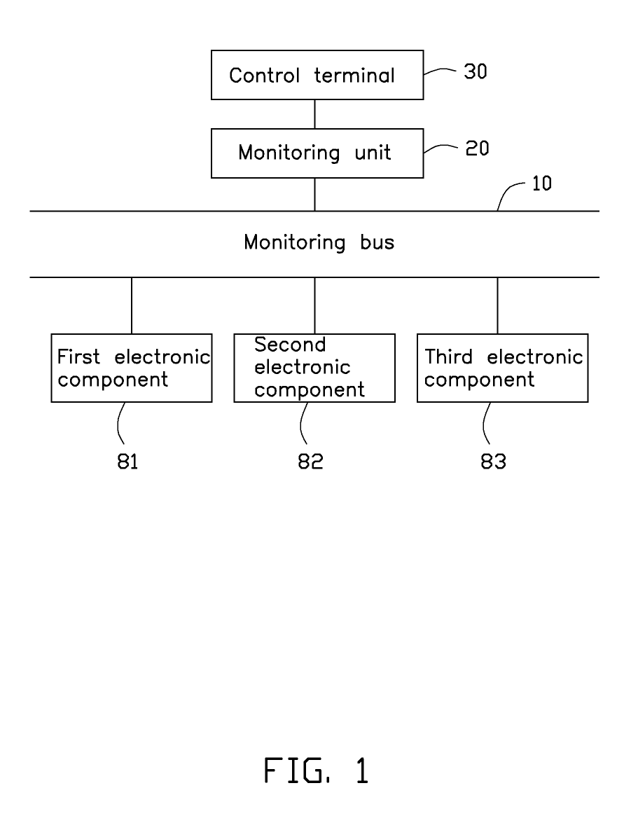

FIG. 1 shows a power supply monitoring system according to an embodiment. The power supply monitoring system includes a monitoring unit 20, a monitoring bus 10, and a control terminal 30. The power supply monitoring system can monitor levels of power supplied to different electronic components of a computer. In one embodiment, the power supply monitoring system is used to monitor power supplied to a first electronic component 81, a second electronic component 82, and a third electronic component 83. The first electronic component 81, the second electronic component 82, and the third electronic component 83 are connected to the monitoring bus 10. The monitoring unit 20 is connected to the monitoring bus 10. The control terminal 30 is connected to the monitoring unit 20.

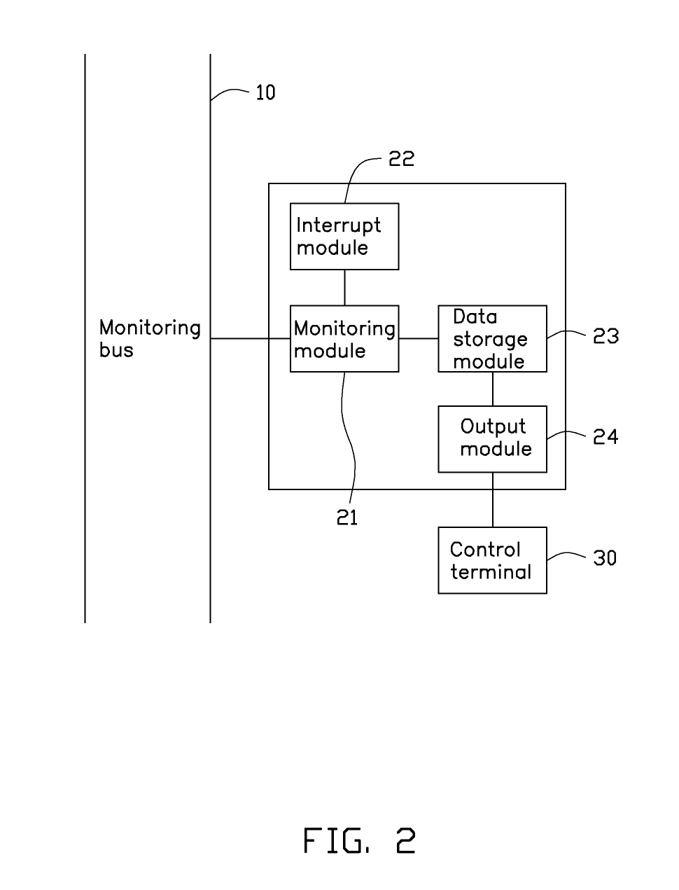

FIG. 2 shows the monitoring unit 20 of the embodiment. The monitoring unit 20 includes a monitoring module 21, an interrupt module 22, a data storage module 23, and an output module 24. The monitoring module 21 is connected to the monitoring bus 10 to monitor power supplied to the first electronic component 81, the second electronic component 82, and the third electronic component 83. The interrupt module 22 is connected to the monitoring module 21 to generate an interrupt signal when the monitoring module 21 has detected variations of the levels of power supplied to the electronic components. The interrupt module 22 interrupts the monitoring module 21 by outputting the interrupt signal to the monitoring module 21.

The data storage module 23 is connected to the monitoring module 21. When the monitoring module 21 has monitored the variations of the levels of power supplied to the electronic components and the monitoring module 21 is interrupted by the interrupt module 22, the monitoring module 21 records and stores the variations of the levels of power supplied to the electronic components into the data storage module 23.

The output module 24 is connected between the data storage module 23 and the control terminal 25. The variations of the levels of power supplied to the electronic components can be transmitted to the control terminal 25 via the output module 24. Operators can examine the variations and analyze the variations to oversee the power supply to the electronic components.

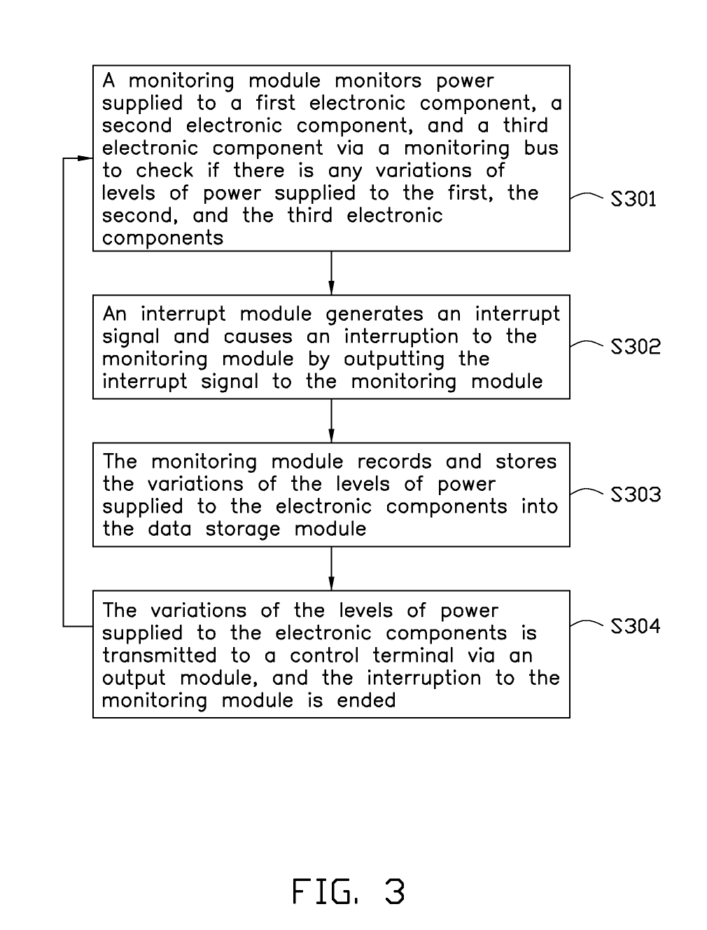

FIG. 3 shows an embodiment of a flow chart of a power supply monitoring method, which includes following steps:

In step S301, the monitoring module 21 monitors power supplied to the first electronic component 81, the second electronic component 82, and the third electronic component 83 via the monitoring bus 10 to check if there is any variations of levels of power supplied to the first, the second, and the third electronic components. If there is a variation, go to step S302.

In step S302, the interrupt module 22 generates an interrupt signal and interrupts the monitoring module 21 by outputting the interrupt signal to the monitoring module 21.

In step S303, the monitoring module 21 records and stores the variations of the levels of power supplied to the electronic components into the data storage module 23.

In step S304, the variations of the levels of power supplied to the electronic components is transmitted to the control terminal 25 via the output module 24, and the interruption to monitoring module 21 is ended, and then go back to step S301.

According to the above power supply monitoring system, the variations of the levels of power supplied to the electronic components are stored in the data storage module 23 and can be examined according to the control terminal 30.

It is to be understood, however, that even though numerous characteristics and advantages of the embodiments have been set forth in the foregoing description, together with details of the structure and functions of the embodiments, the disclosure is illustrative only, and changes may be made in detail, especially in the matters of shape, size, and arrangement of parts within the principles of the present disclosure to the full extent indicated by the broad general meaning of the terms in which the appended claims are expressed.

What is claimed is:

1. A power supply monitoring system for monitoring power supplied to electronic components, comprising:
a monitoring bus connected to electronic components;
a monitoring module configured to monitoring variations of levels of power supplied to the electronic components via the monitoring bus;
an interrupt module configured to interrupt the monitoring module when the monitoring module has monitored the variations of levels of power supplied to the electronic components; and
a data storage module connected to the interrupt module, the interrupt module being configured to store the variations of levels of power supplied to the electronic components into the data storage module when the interrupt module is interrupted.

2. The power supply monitoring system of claim 1, comprising an output module connected to the data storage module.

3. The power supply monitoring system of claim 2, further comprising a control terminal connected to the output module, wherein the variations of the levels of power supplied to the electronic components is transmitted to the control terminal via the output module.

4. The power supply monitoring system of claim 1, wherein the interrupt module is configured to generate an interrupt signal.

5. The power supply monitoring system of claim 4, wherein the monitoring module is interrupted by the interrupt signal output to the monitoring module.

6. A power supply monitoring method, comprising:
monitoring power supplied to electronic components via a monitoring bus by a monitoring module;
causing an interruption to the monitoring module by an interrupt module when the monitoring module has monitored variations of levels of power supplied to the electronic components; and
storing the variations of levels of power supplied to the electronic components into a data storage module when the monitoring module is interrupted.

7. The power supply monitoring method of claim 6, further comprising transmitting the variations of levels of power supplied to the electronic components to a control terminal after the variations of levels of power supplied to the electronic components are stored into the data storage module.

8. The power supply monitoring method of claim 7, comprising ending the interruption to the monitoring module after the variations of levels of power supplied to the electronic components is transmitted to a control terminal

9. The power supply monitoring method of claim 7, comprising connecting an output module between the data storage module and the control terminal.
